(19) United States
(12) Patent Application Publication
(10) Pub. No.: US 2016/0090978 A1
(43) Pub. Date: Mar. 31, 2016

(54) SINGLE ACTUATOR-OPERATED COOLING JET APPARATUS

(71) Applicant: Jung-Hoon KIM, Daegu (KR)

(72) Inventor: Jung-Hoon KIM, Daegu (KR)

(21) Appl. No.: 14/892,926

(22) PCT Filed: Apr. 17, 2014
(86) PCT No.: PCT/KR2014/003357

§ 371 Date: Nov. 20, 2015

(30) Foreign Application Priority Data
Jun. 10, 2013 (KR) 10-2013-0065880

(51) Int. Cl. F04B 43/04; H05K 7/20

(52) U.S. Cl. CPC F04B 43/046; H05K 7/20172

(57) ABSTRACT

Provided is a cooling spray device using a piezoelectric element, comprising an air spray body having a space part formed by coupling, to be airtight, upper and lower layer surfaces formed of resin and/or metal material and provided with a disc-type piezoelectric plate having the piezoelectric property to cross the space part, thereby dividing the space part into first and second chambers, wherein, at least one air pathway for connecting the space part to the outside so as to make air flow into or out from the space part is formed at one side of the air spray body, an air separation film formed by protruding towards the air pathway so as to separate air to be sucked in from air to be discharged is formed at one side of the piezoelectric plate.

### TECHNICAL FIELD

The present invention relates to a cooling jet apparatus using the bending displacement of a piezoelectric element.

### BACKGROUND ART

In general, electronic appliances generate heat when continuously used, and suffer from performance deterioration or reduced lifespan due to the generated heat. Thus, such electronic appliances typically incorporate a cooling apparatus.

Although fan type cooling apparatuses have mainly been used in the related art, cooling apparatuses using a fan have disadvantages such as, for example, excessive noise generation, complexity of manufacturing methods, difficulty in the reduction of the thickness thereof, and poor durability.

As efforts to solve the problems mentioned above, cooling apparatuses using the bending displacement of a piezoelectric element have recently been developed.

In one example, as illustrated in FIG. 1, as air is repeatedly suctioned into and jetted from a cooling apparatus through the expansion and contraction of the cooling apparatus caused by the bending displacement of a piezoelectric plate that is provided with piezoelectric elements vibrating at scores of hertz or more, the air is directly blown to a heat generating region to thereby reduce the temperature of the corresponding region. This cooling apparatus uses a synthetic jet produced when an air stream is jetted through a fine hole.

The efficiency of the synthetic jet varies depending on the flow rate of air and the cross-sectional area of an outlet, and the efficiency is determined depending on the amount of air that is jetted and the size of the outlet. That is, the formation of a jet stream is impossible when the cross-sectional area of the outlet is vary large compared to the amount of air that is jetted, or when a plurality of outlets is formed in several directions.

The cooling apparatus illustrated in FIG. 1 is operated to suction air once and to discharge the suctioned air once in response to the bending displacement of the piezoelectric elements. Since substantial dissipation of heat is realized by the discharge of air, when the suction and discharge of air alternately occur, air discharge is discontinuous, causing deterioration in the effectiveness of the cooling apparatus. In addition, as the piezoelectric elements are provided at the upper and lower sides of the cooling apparatus so as to generate bending displacement, additional elements such as, for example, a clip holder, a package, and a bracket, are additionally required to fixedly install the cooling apparatus. Therefore, when the cooling apparatus is installed to a small electronic appliance, the installation of the cooling apparatus is inconvenient because the cooling apparatus occupies a large space due to the increased installation area and thickness thereof.

In addition, because conventional synthetic jet type cooling apparatuses have no partition capable of dividing an air stream near jet holes, it is impossible to avoid interfering with the introduction and discharge of air, which deteriorates the effectiveness of the jet stream.

### DISCLOSURE

### Technical Problem

Therefore, it is an object of the present invention to provide a cooling jet apparatus, which efficiently dissipates heat via continuous air discharge operation thereof, and is operated by a single actuator which may be installed even in a small electronic appliance.

### Technical Solution

In accordance with one aspect of the present invention, the above and other objects can be accomplished by the provision of a cooling jet apparatus using a piezoelectric element, wherein the cooling jet apparatus includes an air jet device 4 defining a space via sealing coupling of upper and lower walls 6 and 8 formed using a resin material and/or a metal material, a disk type piezoelectric plate 10a being installed across the space to divide the space into first and second chambers 14 and 16, wherein at least one air passage 12 is formed in one side of the air jet device 4 so as to communicate the space with an outside for introduction or discharge of air into or from the space, wherein an air division film 28 is formed at one side of the piezoelectric plate 10a so as to protrude from the air passage 12, and serves to separate air to be suctioned from air to be discharged, and wherein suction and discharge of air occur simultaneously as the first and second chambers 14 and 16 alternately expand and contract by bending displacement of the piezoelectric plate 10a, whereby a heat generating element is cooled via continuous jetting of the air by the air jet device 4.

In addition, in accordance with another aspect of the present invention, there is provided a cooling jet apparatus using a piezoelectric element, wherein the cooling jet apparatus comprises an air jet device 4a defining a space via sealing coupling of upper and lower walls 6 and 8 formed using a resin material and/or a metal material, an elastic layer 30 defining an intermediate layer being formed in the space, and a bender type piezoelectric plate 10b being installed at one side of the elastic layer 30 to divide the space into first and second chambers 14 and 16, wherein at least one air passage 12 is formed in the lower wall 8 of the air jet device 4a so as to communicate the second chamber 16 with an outside for introduction or discharge of air into or from the second chamber, wherein at least one auxiliary communication hole 32 is formed in one side of the first chamber 14 of the air jet device 4a so as to communicate the first chamber 14 with the outside for introduction or discharge of air into or from the first chamber, and wherein the first and second chambers 14 and 16 repeatedly expand and contract as the elastic layer 30 having the piezoelectric plate 10b attached thereto moves up and down by up-and-down bending displacement of the piezoelectric plate 10b, whereby a heat generating element is cooled via jetting of air caused by suction and discharge of air through the air passage 12 and the auxiliary communication hole 32.

### Advantageous Effects

The present invention has the effect of efficiently dissipating heat by continuously discharging air in order to control the generation of heat from heat generating elements by a cooling apparatus using a single piezoelectric element.

In addition, the cooling apparatus may be installed within an electronic appliance without a separate bracket, which ensures easy assembly. In particular, in the case where a plurality of cooling apparatuses is installed such that they are stacked one above another, the cooling apparatuses may be attached to one another, which ensures easy installation.

### DESCRIPTION OF DRAWINGS

FIG. 1 is a schematic view illustrating the operating configuration of a conventional cooling apparatus using piezoelectric elements,

FIGS. 2a and 2b are perspective views of a cooling jet apparatus according to a first embodiment of the present invention,

FIG. 3 is an exploded perspective view of FIG. 2,

FIGS. 4a and 4b are schematic views of the cooling jet apparatus according to the first embodiment of the present invention,

FIG. 5a is a sectional view illustrating piezoelectric plates having a double-layer structure according to the present invention,

FIG. 5b is a sectional view illustrating air jet devices stacked one above another in two stages according to the present invention,

FIG. 5c is a view illustrating a stack of air jet devices, in which air passages of the air jet devices are arranged at left and right sides to cross each other,

FIG. 6 is a sectional view illustrating the configuration of a cooling jet apparatus according to a second embodiment of the present invention,

FIG. 7 is an internal perspective view of FIG. 6,

FIGS. 8 and 9 are views illustrating the configuration of adhesive portions for the installation of the cooling jet apparatus according to the present invention;

FIG. 10 is a schematic view of the cooling jet apparatus according to the second embodiment of the present invention,

FIGS. 11 and 12 are views illustrating reinforcement ribs used to increase the cooling efficiency of the cooling jet apparatus according to the present invention,

FIGS. 13a and 13b are views illustrating the shape of an auxiliary communication hole according to the present invention,

FIGS. 14a and 14b are views illustrating a multi-layered elastic layer according to the present invention,

FIG. 15 is a view illustrating an auxiliary communication hole formed in the side wall of the air jet device according to the present invention,

FIG. 16 is a view illustrating a modified form of the first embodiment of the present invention,

FIG. 17 is a view illustrating a modified form of the second embodiment of the present invention,

FIG. 18 is a view illustrating a polymer coating layer formed on an actuator according to the present invention,

FIGS. 19a and 19b are views illustrating the shape of a sealing member according to the present invention,

FIG. 20 is a side sectional view illustrating the configuration in which air is circulated from the rear side through the provision of an air circulation case outside the air jet device according to the present invention,

FIG. 21 is a front sectional view of FIG. 20,

FIG. 22 is a plan view illustrating the circulation of air introduced from the rear side of the air jet device, and

FIGS. 23 and 24 are views illustrating the improved circulation of air introduced from the rear side of the air jet device.

### BEST MODE

Hereinafter, exemplary embodiments of the present invention will be described in detail with reference to the accompanying drawings.

The present invention is related to a cooling jet apparatus using a piezoelectric element, in which the piezoelectric element in the form of a thin film is provided inside a circular or square device so that air is suctioned into and discharged from air passages via bending displacement caused by piezoelectric effects, thereby achieving dissipation of heat emitted from an electronic appliance.

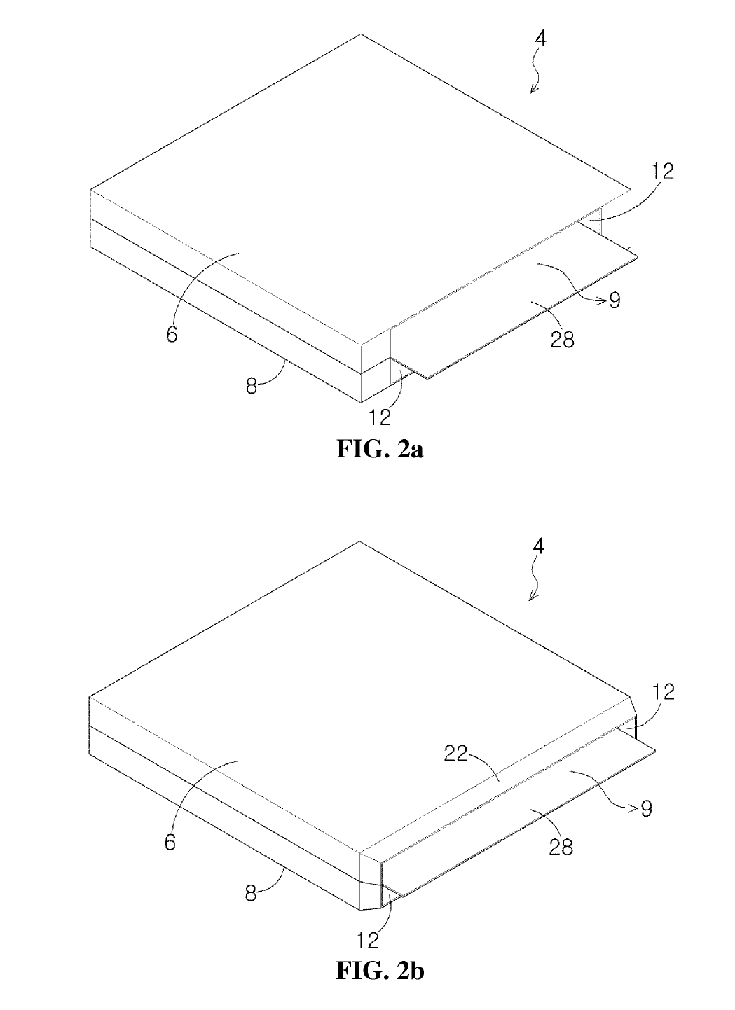

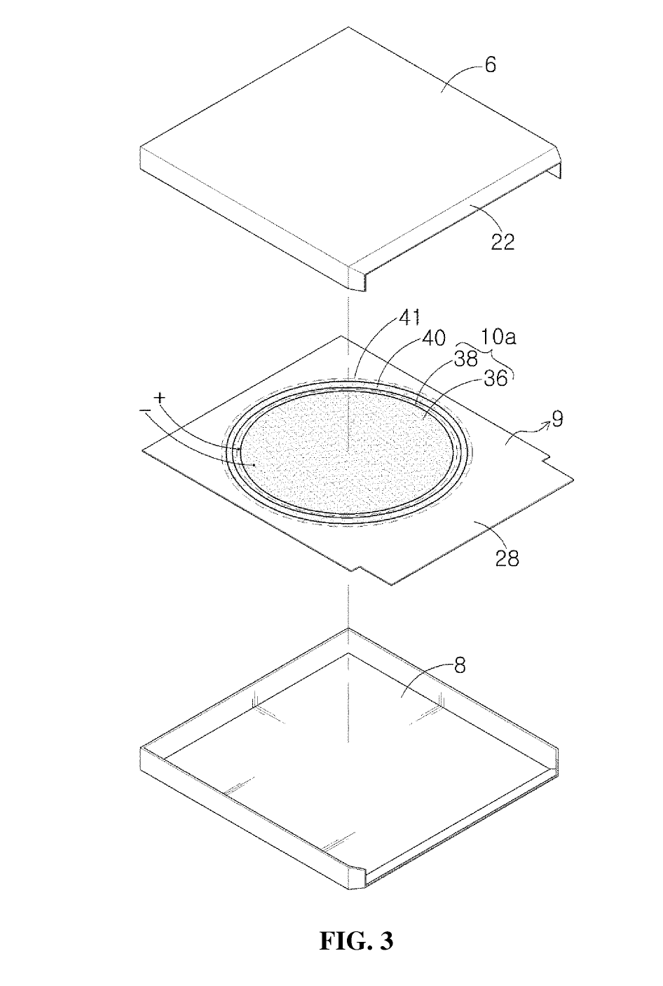

FIGS. 2a and 2b are perspective views of a cooling jet apparatus, which is operated using a single piezoelectric element, according to a first embodiment of the present invention, and FIG. 3 is an exploded perspective view of FIG. 2b.

The cooling jet apparatus of the present invention includes an air jet device 4, which has a circular or square shape and defines a space therein. An actuator 9 having a disk type piezoelectric plate 10a is installed between upper and lower walls 6 and 8 constituting the air jet device 4 so as to be parallel to the upper and lower walls 6 and 8.

In the embodiment of the present invention, the piezoelectric plate 10a may be a bimorph type piezoelectric plate 10a, which is a metal plate having two flexible bending surfaces. As needed, a unimorph type or multimorph type piezoelectric plate 10a, for example, may be installed.

The upper and lower walls 6 and 8 constituting the air jet device 4 may be formed using a resin plate or a metal plate. The coupling rims of the upper wall 6 and the lower wall 8 may be provided with a sealing member 42 for sealing coupling therebetween. The sealing member serves to prevent air from moving in directions excluding an air passage 12 of the air jet device 14, thereby allowing the air to be suctioned and discharged through only the air passage 12.

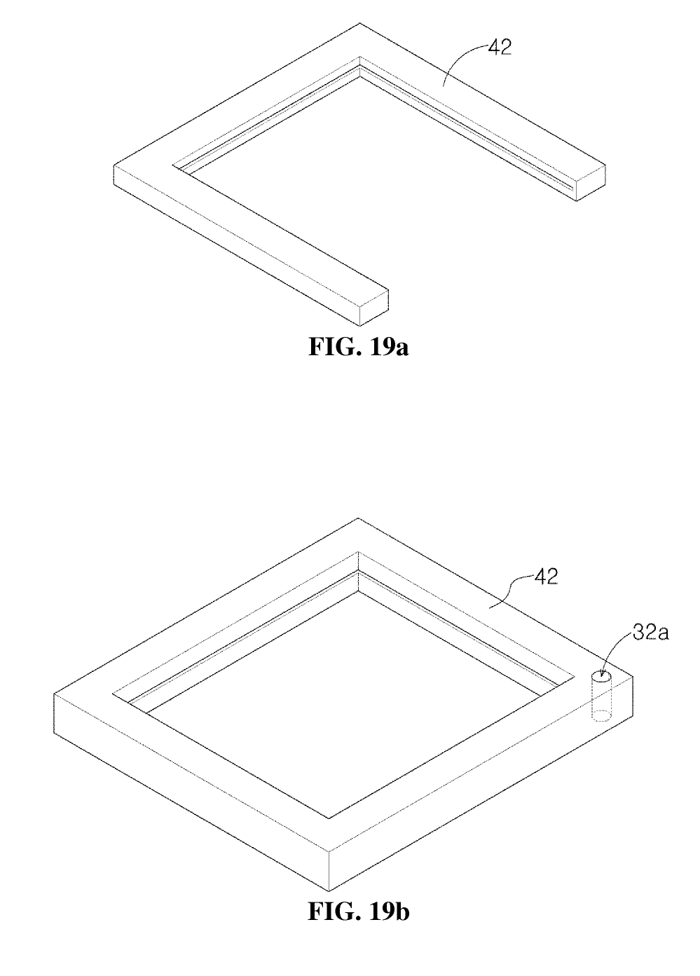

The sealing member 42 is configured, as illustrated in FIG. 19a, such that the actuator 9 may be fitted into and coupled to the sealing member. The sealing member 42 may be formed of rubber or a resin material such as, for example, silicon rubber, urethane resin, synthetic rubber, or natural rubber. The sealing member may be formed of a foam material containing rubber or a resin material.

The air passage 12 may be formed in the center of the air jet device 4 or 4a, or may be deviated to either the left side or the right side in order to adjust the direction in which the air is suctioned and discharged.

The present invention is intended to dissipate heat from an electronic appliance via the suction and discharge of air caused by the bending displacement of the piezoelectric plate 10a which is installed in the inner space of the air jet device 4.

Describing the configuration of the actuator 9 in detail with reference to FIG. 3, the actuator 9 is provided at the core thereof with the piezoelectric plate 10a, which includes a ceramic plate member 36 and a conductive metal member 38 disposed beneath the bottom of the ceramic plate member 36 so as to form an electrode, and an insulation space 40 is defined around the entire edge of the electrode formed by the conductive metal member 38.

The ceramic plate member 36 may be formed of a piezo ceramic. For example, in order to increase the efficiency of the piezoelectric plate 10a, the ceramic plate member may be formed using, for example, a piezo polymer or Electro Active Polymer (EAP).

Among piezo ceramics, for example, a PZT-based, PT-based, or PZT composite-based piezo ceramic may be used. Among piezo polymers, for example, a PVDF, P(VDF-TrFe), or TGS piezo polymer may be used. Among EAPs, for example, an Ionic Polymer Metal Composite (IPMC), Electroactive Polymer Artificial Muscle (EPAM), or Macro Fiber Composite (MFC) polymer, or a polymer composite film containing a conductive filler may be used.

Since current is continuously supplied to the piezoelectric plate 10a of the present invention, in the case where the upper and lower walls 6 and 8 are formed of a metal, there may occur the leakage of current that is supplied through the ceramic plate member 36 and the conductive metal member 38.

Generally, an electronic product may undergo deterioration in cooling performance, and thus malfunction due to the adhesion of dust that occurs at some locations on a current flow path in the electronic product after use for a long time. In the present invention, it is possible to prevent current from leaking outward through the actuator 9, which may reduce the incidence of defective products.

In the present invention, the insulation space 40 is defined around the ceramic plate member 36 and the conductive metal member 38 so that a space is defined between the ceramic plate member 36 and the conductive metal member 38 and a metal portion constituting the actuator 9. As such, the ceramic plate member 36 is installed as through it were to float in the space. In this way, upon high speed vibration, a reduction in vibration noise may be realized because the ceramic plate member 36 is surrounded by a soft film member 41. In addition, the durability of the actuator 9 is increased because vibration caused by the up-and-down bending displacement of the actuator 9 is alleviated using a material having elastic restoring force.

The insulation space 40 is a space in which the annular film member 41 is attached between the conductive metal member 38 and the actuator 9.

The film member 41, configured to define the insulation space 40, may be formed of a synthetic resin film such as, for example, a polyester film, a nylon film, or a polyimide film.

In addition, in order to electrically insulate the ceramic plate member 36 and the conductive metal member 38, through which current is supplied, from the upper and lower walls 6 and 8, as illustrated in FIG. 18, a polymer coating layer 35 may be formed on the remaining portion of the conductive metal member 38 excluding the current supply portion thereof, which may prevent the current from leaking to unnecessary locations.

At this time, the conductive metal member 38 may serve as the actuator 9 without the insulation space 40 defined by the film member 41.

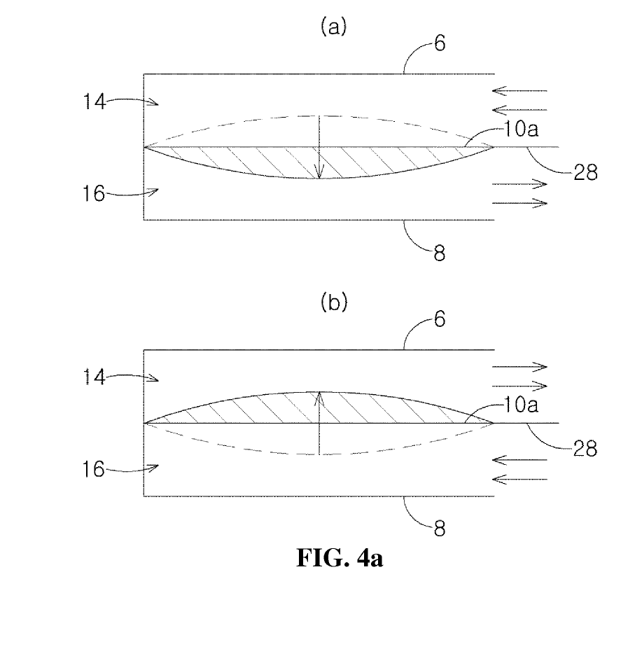

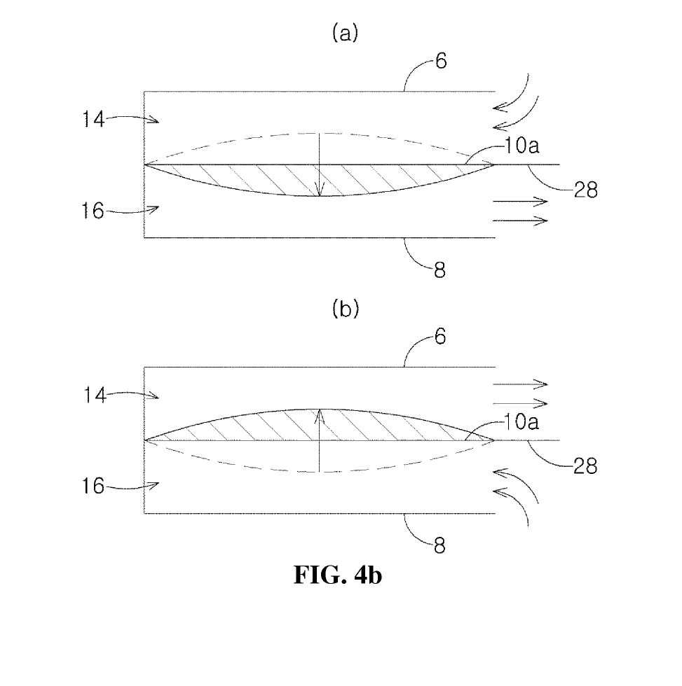

Hereinafter, the operating process of the cooling jet apparatus according to the first embodiment of the present invention will schematically be described with reference to FIGS. 4a and 4b.

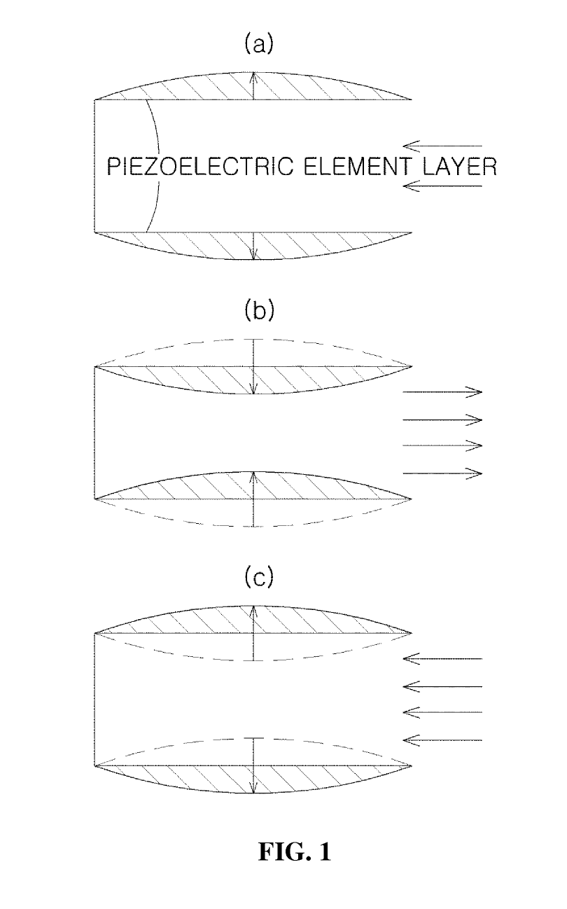

In FIG. 4, (a) and (b) schematically illustrate the flow state of air depending on the bending displacement of the piezoelectric plate 10a. To describe the flow state of air, the following description is given for comparison with the conventional configuration illustrated in FIG. 1.

Prior to the description, in order to assist understanding, the amount of air that is suctioned or discharged by the bending displacement of the piezoelectric plate 10a depending on the expansion and contraction of the piezoelectric element is indicated by the arrows as in FIGS. 1, 4a and 4b. In addition, one arrow indicates the amount of air corresponding to one bending displacement (expansion or contraction) of the piezoelectric plate 10a, and the direction of the arrow indicates the direction in which air is suctioned and discharged.

In addition, when air is discharged from the air jet device 4, the air is jetted in the straight line through the narrow air passage 12. When air is suctioned, the air around the air passage 12 is suctioned in an eddy form, as illustrated in FIG. 4b.

First, considering the conventional configuration with reference to FIG. 1, the upper and lower layers in FIG. 1 respectively form piezoelectric element layers. Thus, upon initial vibration, the upper and lower layers expand, causing outside air to be suctioned inward as illustrated in (a) of FIG. 1. At this time, as the upper and lower layers expand simultaneously, the amount of air that is suctioned is indicated by the two arrows.

When the expanded piezoelectric element layers contract into the space therebetween via the inverse operation thereto, the suctioned air is discharged through the air passage 12. The amount of air that is discharged is indicated by the four arrows as illustrated in (b) of FIG. 1. The reason why the amount of air that is discharged is indicated by the four arrows is that the air is discharged as the piezoelectric element layers undergo bending displacement from the expanded state to the contracted state.

The contracted piezoelectric element layers again expand to thereby suction air, and the amount of suctioned air is indicated by the four arrows as illustrated in (c) of FIG. 1.

That is, since air is suctioned once and then discharged once while bending displacement occurs, the continuous discharge of air is impossible.

Next, the operating configuration of the cooling jet apparatus according to the present invention will be described in detail with reference to FIG. 4a. The air jet device 4 of the present invention is configured in such a manner that the upper and lower walls 6 and 8 thereof are formed using a resin plate or a metal plate and serves to suction or discharge air via expansion and contraction caused by the bending displacement of the single actuator 9 installed in the inner space thereof. The sealing member 42 is provided at the coupling rims of the upper and lower walls 6 and 8 so as to prevent air from moving in directions excluding the air passage 12, thereby allowing the air to be suctioned and discharged only through the air passage 12.

Considering the above configuration, the actuator 9 installed in the space of the air jet device 4 divides the space into first and second chambers 14 and 16 such that there is no air communication between the two chambers.

An air division film 28 is formed on one side of the actuator 9 so as to more protrude from the air passage 12 than the upper and lower walls 6 and 8, thereby serving to divide the air to be suctioned into or discharged from the first and second chambers 14 and 16. When the air division film 28 is not installed, the suction and discharge of air interfere each other, which inhibits the formation of jet flow.

As a result of providing the air passage 12 with the air division film 28, as illustrated in FIG. 4b, it is possible to prevent deterioration in the effects of the jet flow caused when the eddy flow of suctioned air interferes with the linear jet flow of discharged air.

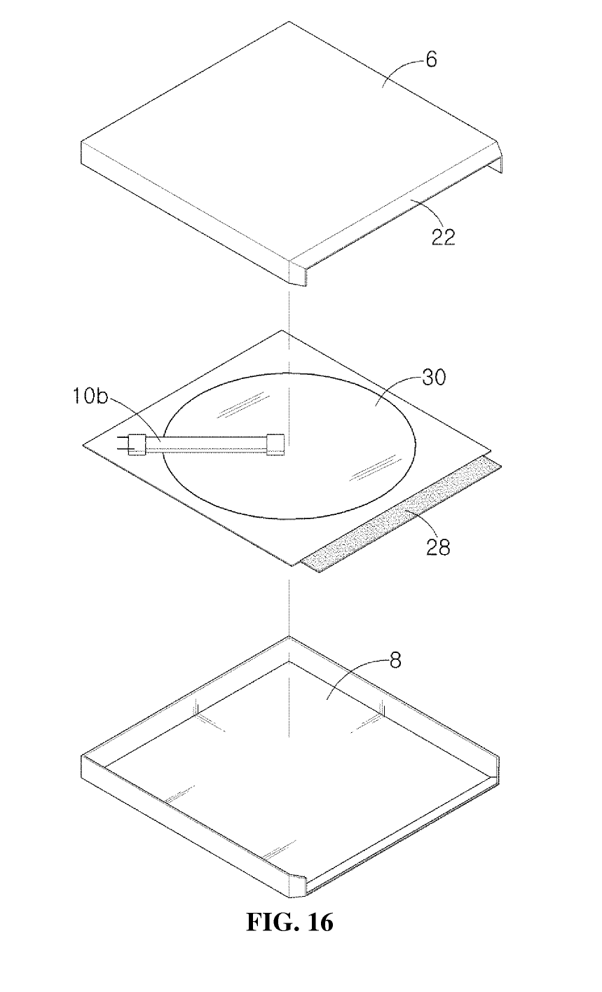

The air division film 28 may be formed of a different material from that of the actuator 9, so as to ensure the effective jet of air to be discharged. In one embodiment of the present invention, as illustrated in FIG. 16, the air division film 28 may be formed using an elastic synthetic resin film.

In the present invention, when a voltage is applied to the piezoelectric plate 10a, as illustrated in (a) of FIGS. 4a and 4b, the piezoelectric plate undergoes bending displacement to one side. At this time, the inner space of the first chamber 14 expands to suction outside air, and the second chamber 16 contracts to discharge inside air.

The piezoelectric plate 10a, which is bent to one side, is again bent in the opposite direction as illustrated in (b) of FIGS. 4a and 4b. At this time, the first chamber 14, which has expanded by the bending displacement of the piezoelectric plate 10a, contracts to discharge the air, and the contracted second chamber 16 expands to suction outside air.

That is, as the piezoelectric plate 10a undergoes bending displacement by vibrating at scores of hertz or more, as illustrated in FIGS. 4a and 4b, the continuous discharge of air is possible.

As described above, the air jet device 4 of the present invention performs the suction and discharge of air simultaneously when the piezoelectric plate 10a undergoes bending displacement once. In addition, comparing the amount of discharged air, in the case of FIG. 1 where the suction and discharge of air are alternately repeated in a discontinuous manner, the air corresponding to the four arrows is discharged during a single cycle (the suction and discharge of air by bending displacement).

In the present invention, it will be appreciated that the discharge of air is continuously performed while the piezoelectric plate 10a undergoes bending displacement, which causes the same amount of air corresponding to the four arrows to be discharged.

Accordingly, in a configuration whereby dissipation of heat is controlled by discharging the same amount of air on a per cycle basis corresponding to a single bending displacement, it can be said that reducing the temperature of a heat generating element via the continuous discharge of air using the single actuator 9 is more efficient than using two actuators 9 each provided with the piezoelectric plate 10a.

In addition, the configuration using the single actuator 9 has the effect of reducing vibration noise and current consumption by half.

The air jet device 4 according to the embodiment of the present invention may be manufactured into various forms suitable for the shape of an attachment surface on the electronic appliance. The air jet device 4 may have a circular or square form. Even in the case where a plurality of air jet devices 4 is stacked one above another as needed, the air jet devices 4 may be simply installed by being attached to one another using an adhesive. In the case where the air jet devices 4 are installed in the horizontal direction, the side surfaces of the air jet devices 4 may be attached to one another so as to be installed in an elongated form.

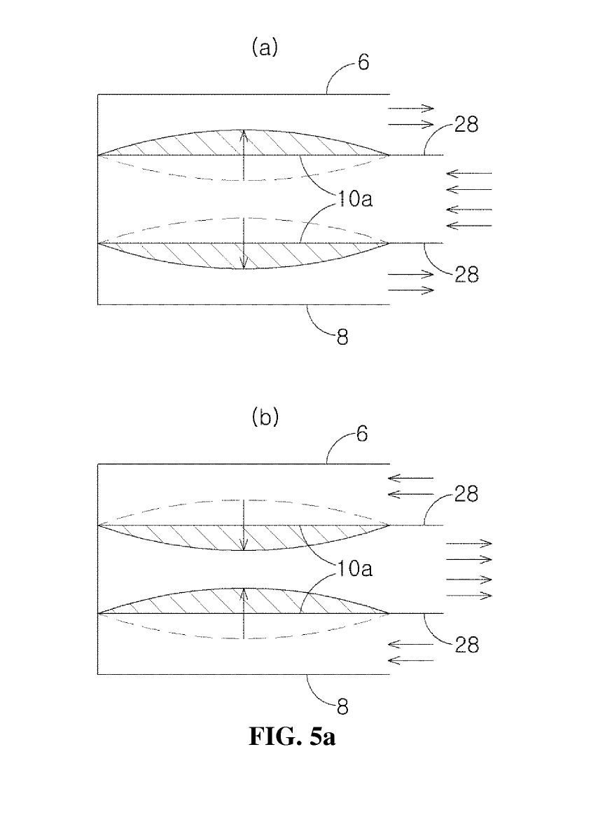

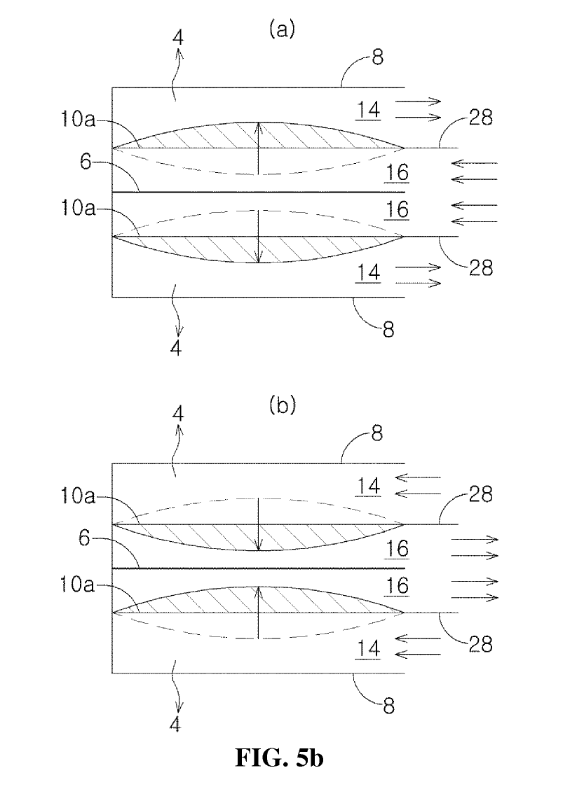

FIG. 5a illustrates a configuration in which the piezoelectric plates 10a, having a double-layer structure, are installed inside the air jet device 4 according to the present invention.

As illustrated in (a) and (b) of FIG. 5a, when the piezoelectric plates 10a are installed in a double-layer structure, the amount of air that is suctioned and discharged is increased, which may ensure effective cooling of a heat generating element. In the embodiment of the present invention, although the piezoelectric plates 10a having a double-layer structure are provided as illustrated in FIG. 5a, a multilayered piezoelectric plate structure may be considered in order to increase cooling efficiency as needed.

FIG. 5b illustrates a configuration in which the air jet devices 4 are stacked one above another according to the present invention.

When the air jet devices 4 are vertically stacked one above another, the suction and discharge of air through the air passages 12 cross each other at attachment positions between the air jet devices 4, thus causing interference between the jet streams.

In the present invention, first, the lower wall 8 of the first-stage air jet device 4 is attached and fixed inside the electronic appliance, and the second-stage air jet device 4 is installed on the first-stage air jet device so as to be oriented upside down. That is, the upper wall 6 of the first-stage air jet device 4 comes into contact with the upper wall 6 of the second-stage air jet device 4.

As the upper and lower air jet devices 4 are stacked one above another so as to suction and discharge air in the same direction depending on the bending displacement of the piezoelectric plates 10a, the amount of air that is suctioned and discharged is doubled without interference between the jet streams of the air jet devices 4, which may increase the effectiveness of cooling.

In addition, as described above, in the case where the air passage 12 of the air jet device 4 is deviated to either the left side or the right side, as illustrated in FIG. 5c, the air passages 12 of the air jet devices 14 stacked one above another cross each other in the left and right direction, thus avoiding interference between the jet streams.

In the cooling jet apparatus of the present invention, a jet induction surface 22 may be formed at the entrance edge of the air passage 12 so as to concentrate the jetted air on the heat generating element.

The jet induction surface 22 is inclined inward of the jetting direction to enable the intensive jetting of air, thereby collecting the air to be discharged in the radial direction. This enables the air to be jetted so as to be concentrated on a specific portion to be cooled. In addition, in order to allow the air to be intensively jetted far away, the jet induction surface 22 may take the form of

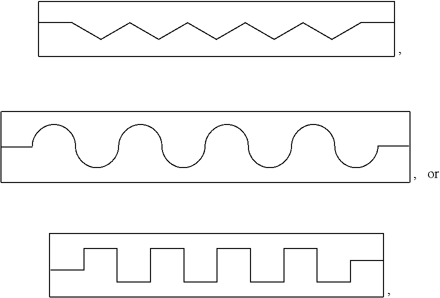

so as to induce the jetting of air.

In addition, in order to allow the discharged air to be further concentrated while passing through the air division film 28, the air division film 28 may take the form of

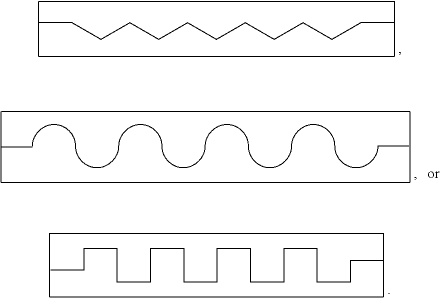

As the air division film 28 is formed into the form described above, the air is discharged along a virtual air jet path so as to be further concentrated.

Here, the air division film 28 may be formed into a plane, and the jet induction surface 22 may be formed to have the same curvature as the air division film 28 so as to define a virtual air jet path, which enables the intensive jetting of air.

The cooling jet apparatus according to the embodiment of the present invention normally has a size of approximately 40 mm×40 mm×2 mm. When the cooling jet apparatus is installed to, for example, a mobile terminal, and thus a space for installation thereof is narrow, the cooling jet apparatus may have a size of 15 mm×15 mm×1 mm or less.

When the size and thickness of the cooling jet apparatus are reduced, it is necessary to reduce the thickness of the disk type piezoelectric plate 10a, which may reduce piezoelectric effects. To solve this problem, an EPA or polyvinylidene fluoride (PVDF) piezoelectric plate, which exhibits large displacement, may be used. In addition, it is effective to use an elastic layer 30 using a bender type piezoelectric plate 10b, which will be described below.

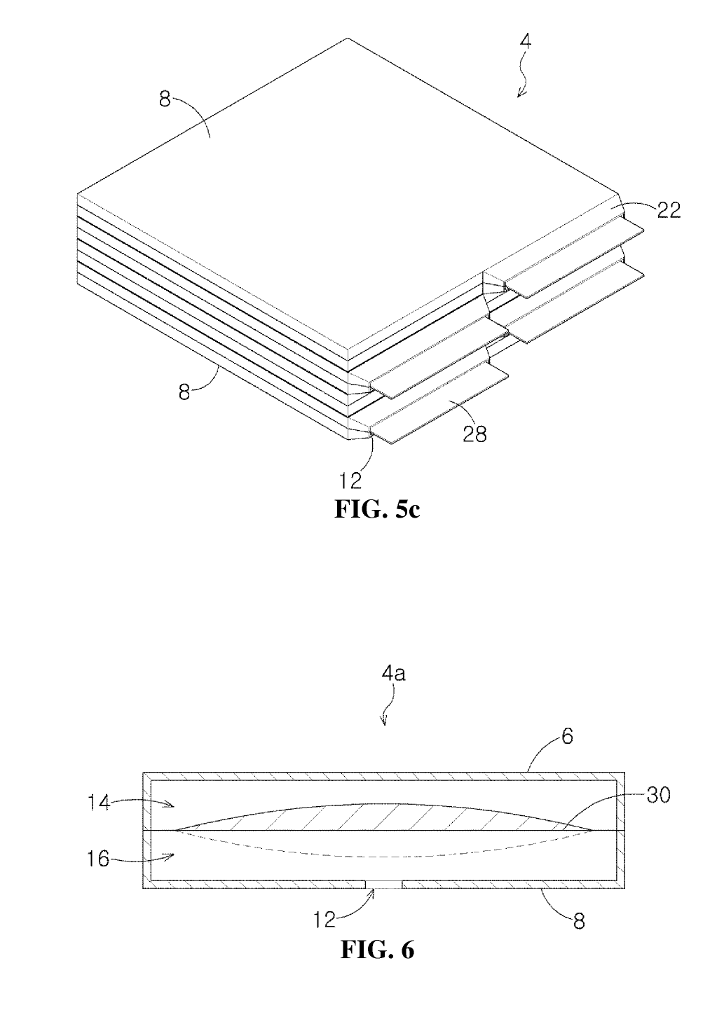

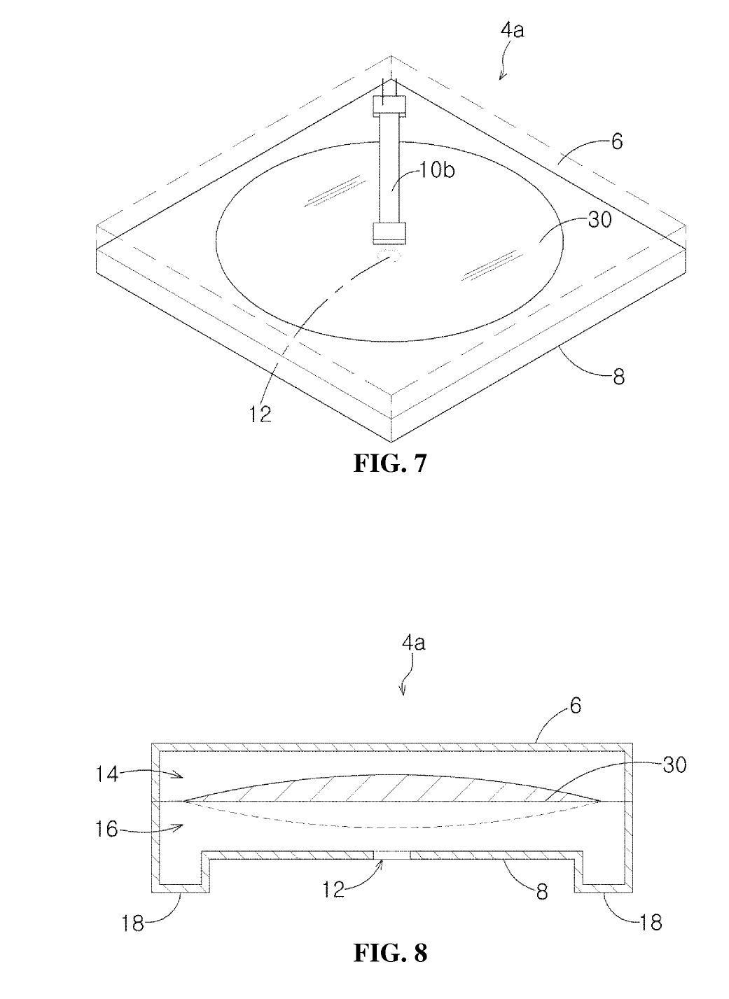

FIG. 6 is a sectional view illustrating the configuration of a cooling jet apparatus according to a second embodiment of the present invention, and FIG. 7 is a perspective view illustrating the internal configuration.

The cooling jet apparatus according to the present invention may be provided with the bender type piezoelectric plate 10b and the elastic layer 30, which exhibit large bending displacement, so as to efficiently dissipate heat from a heat generating element via the jetting of air.

Explaining the cooling jet apparatus according to the second embodiment of the present invention in detail with reference to FIGS. 6 and 7, the cooling jet apparatus includes an air jet device 4a, which is configured in a hermetically sealed form and includes the upper and lower walls 6 and 8 formed using a resin plate or a metal plate and the elastic layer 30 provided as an intermediate layer.

The elastic layer 30 is formed of, for example, silicon, urethane, a synthetic resin, or a rubber material, but any other film-shaped materials may be used so long as it has elasticity and durability.

The air passage 12 is formed in the lower wall 8 of the air jet device 4a to allow air to be introduced into the sealed space inside the air jet device. The most preferable position for the air passage 12 is the center of the air jet device 4a. The position at which the air passage is formed may be changed as needed. Although a plurality of air passages 12 and auxiliary communication holes 32a and 32b may be formed, it is effective to form the air passage 12 on a per chamber basis.

The bender type piezoelectric plate 10b is attached to the elastic layer 30 which forms the intermediate layer of the air jet device 4a. One end of the piezoelectric plate 10b is a fixing end for attachment, and the other end is attached to the center of the elastic layer 30. One or more piezoelectric plates 10b may be installed depending on the size of the air jet device 4a, or the piezoelectric plate 10b may have a length equal to the diameter of the elastic layer 30 so as to be attached to the entire elastic layer 30. At this time, both ends of the piezoelectric plate 10b serve as fixing ends to allow up-and-down bending motion.

When the piezoelectric plate 10b having one fixing end undergoes bending displacement by piezoelectric effects, the other free end of the piezoelectric plate repeatedly undergoes up-and-down motion, causing the elastic layer 30 to repeatedly expand and contract.

The air jet device 4a according to the present invention is installed by being attached and fixed at the lower wall 8 thereof to the top of a heat generating element. To ensure the suction and discharge of air through the air passage 12 formed in the lower wall 8, it is necessary to space the air jet device apart from the attachment surface.

To this end, as illustrated in FIGS. 8 and 9, the air jet device 4a is provided at the lower end thereof with a plurality of adhesive portions 18, which allows the air jet device 4a to be spaced apart from the attachment surface and to be located above the heat generating element.

The adhesive portions 18 are integrally formed with the lower wall 8. As the air jet device 4a is attached and fixed so as to be spaced apart from the attachment surface via the adhesive portions 18, air may be suctioned or discharged into or from a space therebetween.

In addition, in the present invention, adhesive members may be separately provided below the air jet device 4a. After the adhesive members are attached to various positions on the lower wall 8, the air jet device 4a may be installed so as to be spaced apart from the attachment surface.

In the present invention, the air jet device 4a is operated via the bending displacement of the piezoelectric plate 10b. As the elastic layer 30 repeatedly expands and contracts via the bending displacement of the piezoelectric plate 10b which operates at scores of hertz or more, air is repeatedly suctioned and discharged, which may dissipate heat from a heat generating element.

In this way, the air jet device 4a according to the second embodiment of the present invention may efficiently dissipate heat generated from a core element of the electronic appliance, such as a CPU, by directly jetting air from the upper side of the heat generating element.

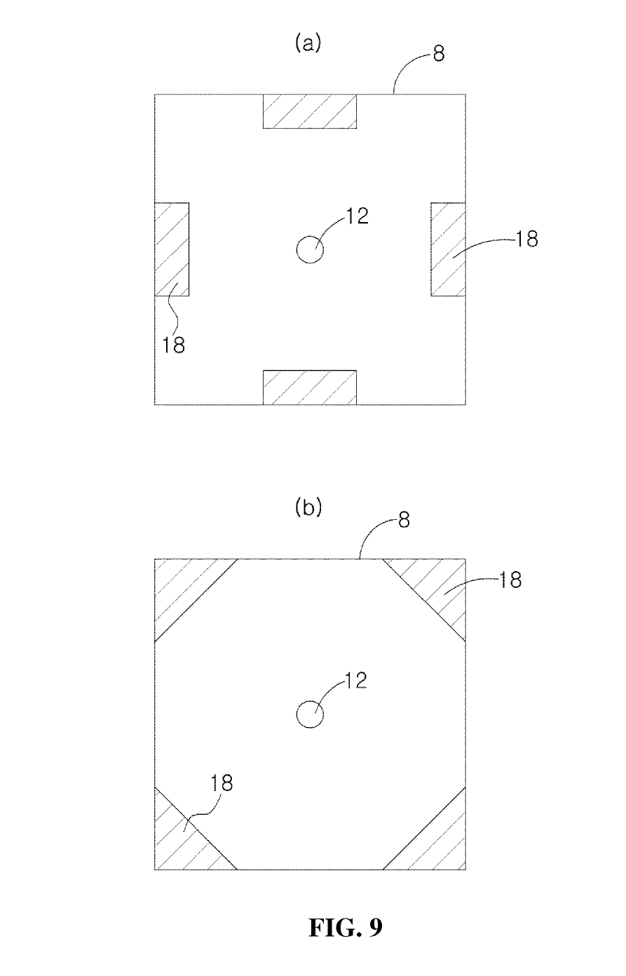

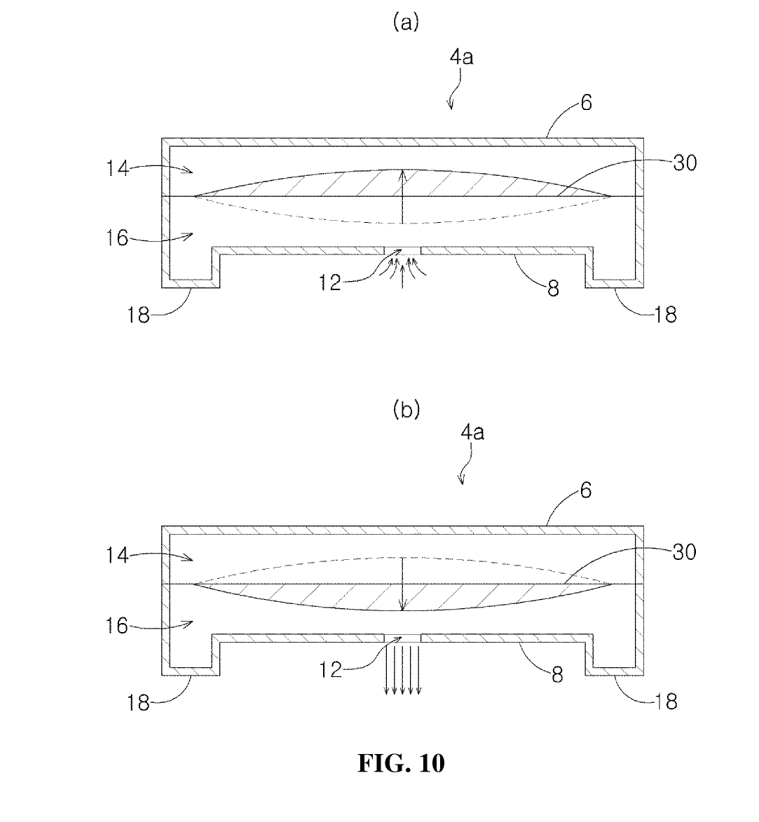

FIG. 10 schematically illustrates the operating process of the cooling jet apparatus according to the second embodiment of the present invention.

In FIG. 10, (a) illustrates the state in which the first chamber 14 contracts as the elastic layer 30 of the air jet device 4a extends by the bending displacement of the piezoelectric plate 10b attached thereto. Through the contraction of the first chamber 14, outside air is suctioned into the air jet device 4a through the air passage 12.

Then, the second chamber 16 contracts as the piezoelectric plate 10b is bent downward as illustrated in (b) of FIG. 10, the suctioned inside air is pushed ti thereby be discharged outward through the air passage 12.

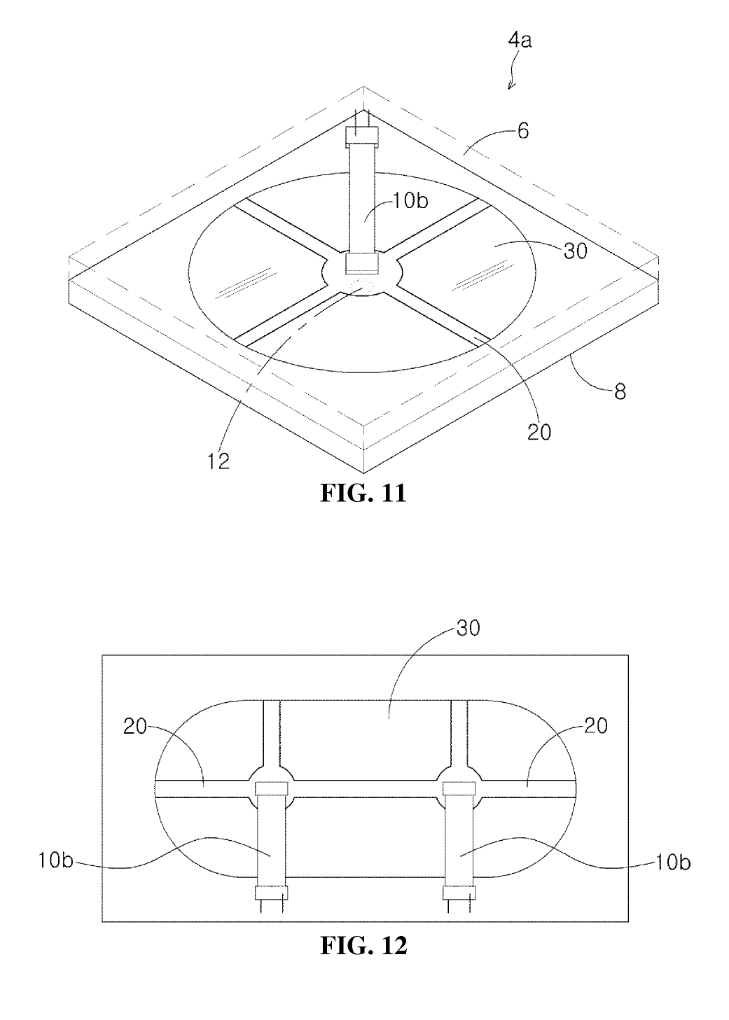

FIG. 11 illustrates a modified form of the second embodiment of the present invention.

The air jet device 4a of the present invention includes reinforcement ribs 20, which serve to increase the amount of air to be suctioned into or discharged from the air jet device 4a when the elastic layer 30 expands or contracts by the bending displacement of the piezoelectric plate 10b, thereby cooling a heat generating element even more effectively.

The reinforcement ribs 20 are formed of a thicker film or a higher strength synthetic resin than the elastic layer 30, and are attached to the elastic layer 30 and coupled to the free end of the piezoelectric plate 10b. That is, it is effective to provide the elastic layer 30 with the reinforcement ribs 20 so that the reinforcement ribs are attached separately from the piezoelectric plate 10b. When the reinforcement ribs 20 and the piezoelectric plate 10b are stacked on the center of the elastic layer 30, the reinforcement ribs 20 are arranged in a circular pattern to allow the elastic layer 30 to expand or contract in a dome shape.

Although one or more reinforcement ribs 20 may be provided, the number of ribs may be determined in consideration of the fact that an excessively great number of ribs may prevent efficient expansion and contraction of the elastic layer 30.

As the reinforcement ribs 20 move up and down when the elastic layer 30 expands and contracts by the bending displacement of the piezoelectric plate 10b, the elastic layer 30 forms a dome shape when it moves up and down, which may increase the amount of air to be suctioned or discharged, resulting in efficient dissipation of heat.

The reinforcement ribs 20 provided at the elastic layer 30 may be provided in a plural number based on the size and shape of the elastic layer 30 as in the embodiment illustrated in FIG. 12.

In the second embodiment of the present invention, the elastic layer 30, which is formed as the intermediate layer inside the air jet device 4a, blocks the communication of air between the first chamber 14 and the second chamber 16. Therefore, there is a requirement for a passage, through which air may be suctioned into or discharged from the first chamber 14 when up-and-down bending of the elastic layer 30 occurs.

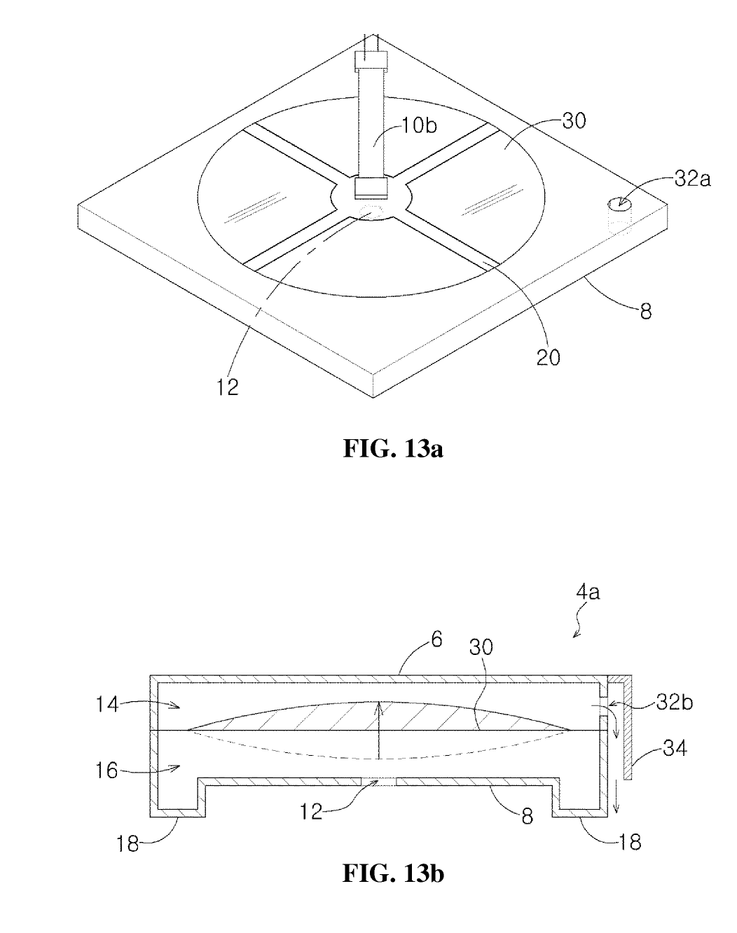

In the present invention, as illustrated in FIGS. 13a and 13b, auxiliary communication holes 32a and 32b for air movement to the first chamber 14 are formed in the side wall of the air jet device 4a so as to enable the suction or discharge of air into or from the first chamber 14 upon the expansion and contraction of the elastic layer 30. The air streams into the auxiliary communication holes 32a and 32b may also be effectively used in the cooling of a heat generating element.

That is, an air stream moving into the first chamber 14 as well as an air stream moving into the second chamber 16 through the air communication hole 12 may contribute to cooling, which results in increased cooling efficiency.

As illustrated in FIG. 13a, the auxiliary communication holes 32a and 32b for air communication of the first chamber 14 are formed in a corner portion of the air jet device 4a.

Since the air jet device 4a according to the exemplary embodiment of the present invention has a square shape and the piezoelectric element forming the elastic layer 30 has a circular shape, the corner portion around the elastic layer 30 is formed of a resin plate or a metal plate. As such, the auxiliary communication hole 32a for air communication of the first chamber 14 is formed in the corner portion of the air jet device 4a so as to communicate with a space beneath.

The auxiliary communication hole 32a does not communicate with the second chamber 16 so as to directly communicate with the space below the air jet device 4a so that outside air is suctioned or air inside the first chamber 14 is discharged through the lower wall 8.

FIG. 13b illustrates another shape of the auxiliary communication hole 32b. In the present invention, the auxiliary communication hole 32b for air communication of the first chamber 14 is formed in the side wall of the air jet device 4a, and an air communication housing 34 is provided outside the side wall of the air jet device 4a so as to allow the air to move through the auxiliary communication hole 32b, thereby enabling downward air communication. In order to increase the efficiency with which air to be discharged downward from the air jet device 4a is jetted, the distal end of the air communication housing 34, from which the air is discharged, may be curved inward to allow the air to be intensively jetted to a heat generating element beneath.

FIGS. 13a and 13b illustrate the downward communication of air inside the first chamber 14. The air passage 12 formed in the lower wall of the air jet device 4a may also be formed in the side wall or the upper wall 6, so as to allow the air inside the first chamber 14 to move leftward or rightward, or upward from the air jet device 4a.

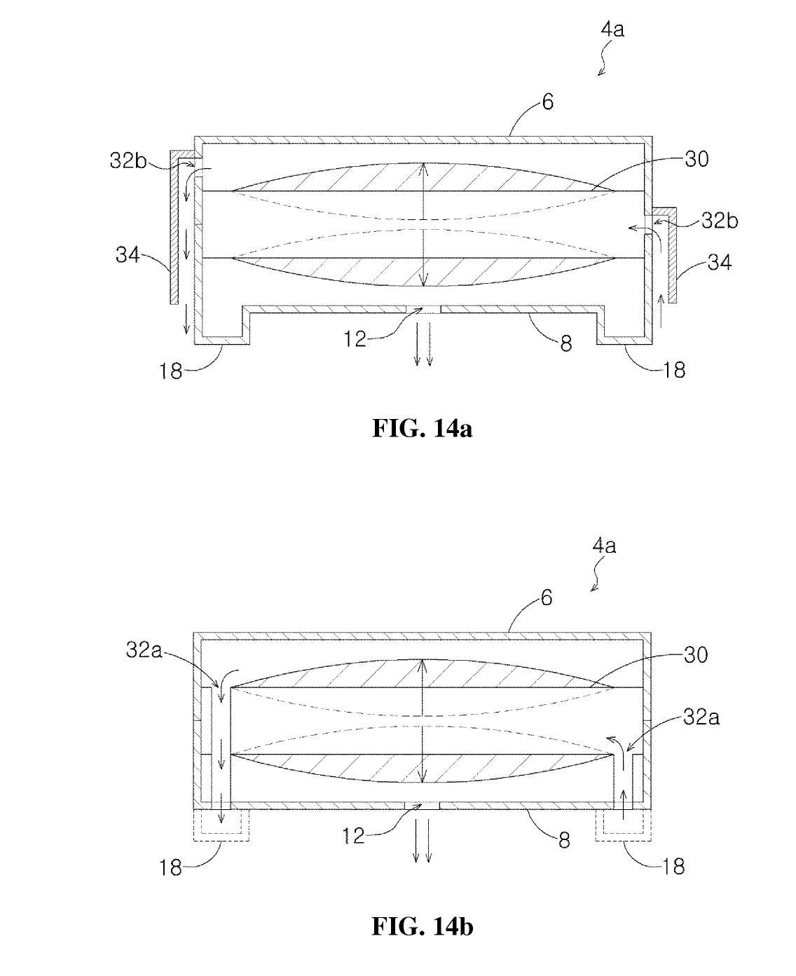

FIGS. 14a and 14b illustrate the elastic layers 30, which are formed in a double-layer structure inside the air jet device 4.

In the case of the elastic layers 30 having a double-layer structure, the auxiliary communication holes 32a and 32b for air communication of the chambers may be formed in a number corresponding to the number of chambers. The elastic layers 30 having a double-layer structure increase the amount of air to be suctioned or discharged, which increases the cooling effect.

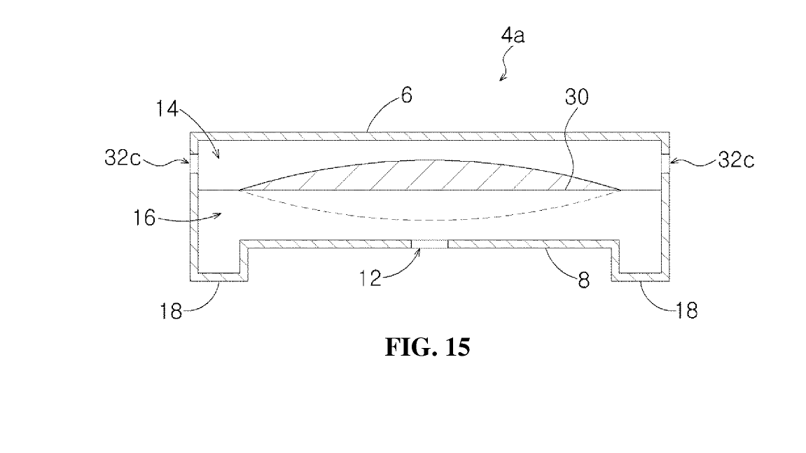

In the present invention, when the air jet device 4a is installed in a mobile terminal having a narrow installation space, the top of the air jet device may be covered and closed by another device. At this time, as illustrated in FIG. 15, an auxiliary communication hole 32c may be formed in the side wall of the air jet device.

As illustrated in FIG. 15, a plurality of auxiliary communication holes 32c for air communication may be formed in the side wall of the air jet device 4a. Since air is discharged through the auxiliary communication holes 32c when the elastic layer 30 expands upward, and outside air is naturally introduced when the elastic layer contracts downward, the elastic layer 30 exhibits easy up-and-down motion via expansion and contraction.

The cooling jet apparatus of the present invention may be configured as in the first embodiment in which the air jet device 4 includes the upper and lower walls 6 and 8 formed using a resin or metal plate and the disk type piezoelectric plate 10a installed as an intermediate layer, or may be configured as in the second embodiment in which the air jet device 4a includes the elastic layer 30 installed as an intermediate layer and the bender type piezoelectric plate 10b is attached to the elastic layer.

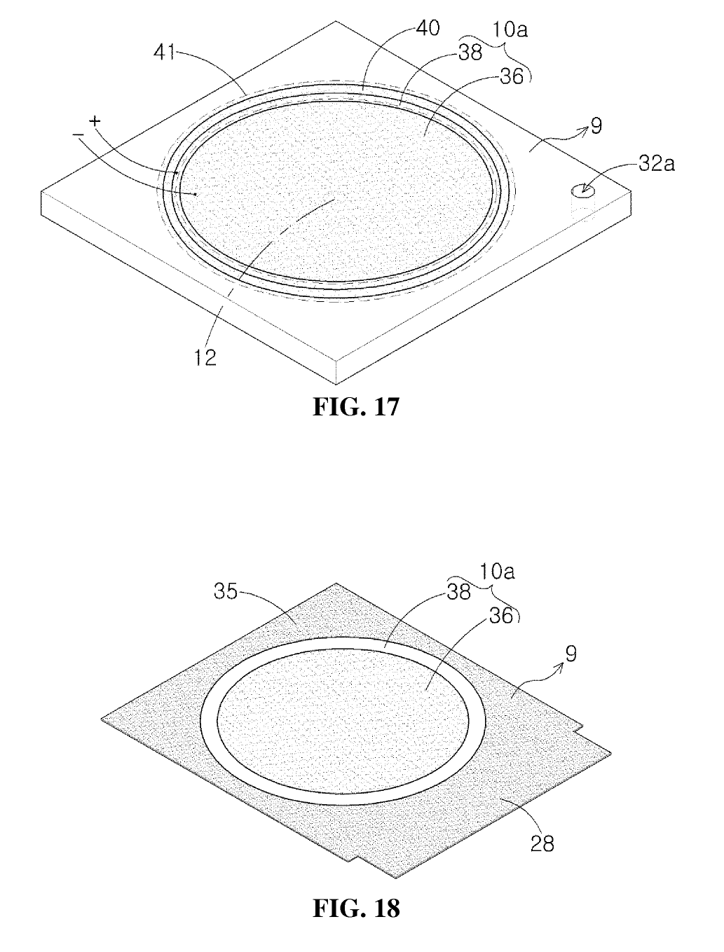

As illustrated in FIGS. 16 and 17, the air jet device 4 according to the first embodiment of the present invention may be modified such that an intermediate layer thereof is formed by the elastic layer 30 and the bender type piezoelectric plate 10b, and the air jet device 4a according to the second embodiment of the present invention may be modified such that an intermediate layer thereof is formed by the disk type piezoelectric plate 10a.

In addition, in order to increase the efficiency with which air is jetted via bending displacement in the case where the air jet device 12 is very thin and light, the piezoelectric plate 10a or 10b and the elastic layer 30 may be formed of EAP or PVDF.

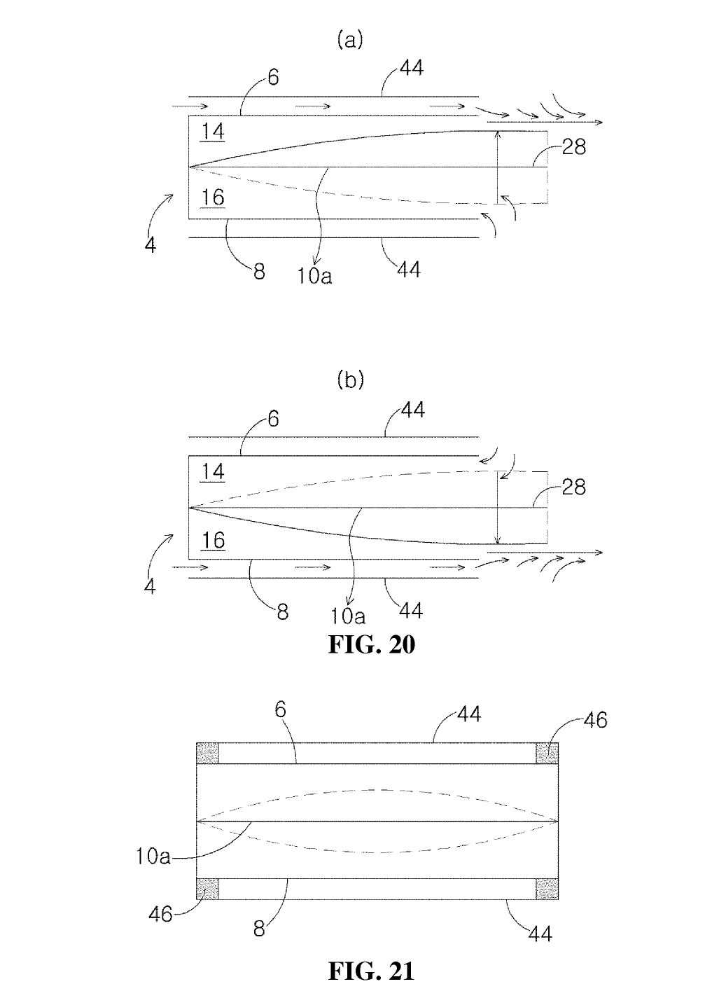

FIGS. 20 to 24 illustrate a configuration in which the air jet device 4 of the present invention is installed in an electronic appliance to circulate outside air to the interior of the electronic appliance.

As illustrated in FIG. 20, in the present invention, an air circulation case 44 is installed outside the air jet device 4. The case 44 is installed to the air jet device via attachment after vibration absorbing members 46 used to reduce vibration noise are attached to the outer periphery of the air jet device 4.

The vibration absorbing members 46 may be formed using, for example, a vibration control tape, a silicon sponge tape, or a Poron tape.

The back of the air circulation case 44 is open. As illustrated in FIGS. 20 and 21, as the piezoelectric plate 10a performs bending displacement, air inside the first and second chambers 14 and 16 is jetted. Based on Bernoulli's principle, the jetted air attracts some of the surrounding air so as to be jetted together with the same.

At this time, in addition to the surrounding air to be jetted, the air between the air jet device 4 and the air circulation case 44 is jetted, thus causing the air supplied from the case 44, the back of which is open, to follow the jetted air to thereby move in the direction in which the air is jetted.

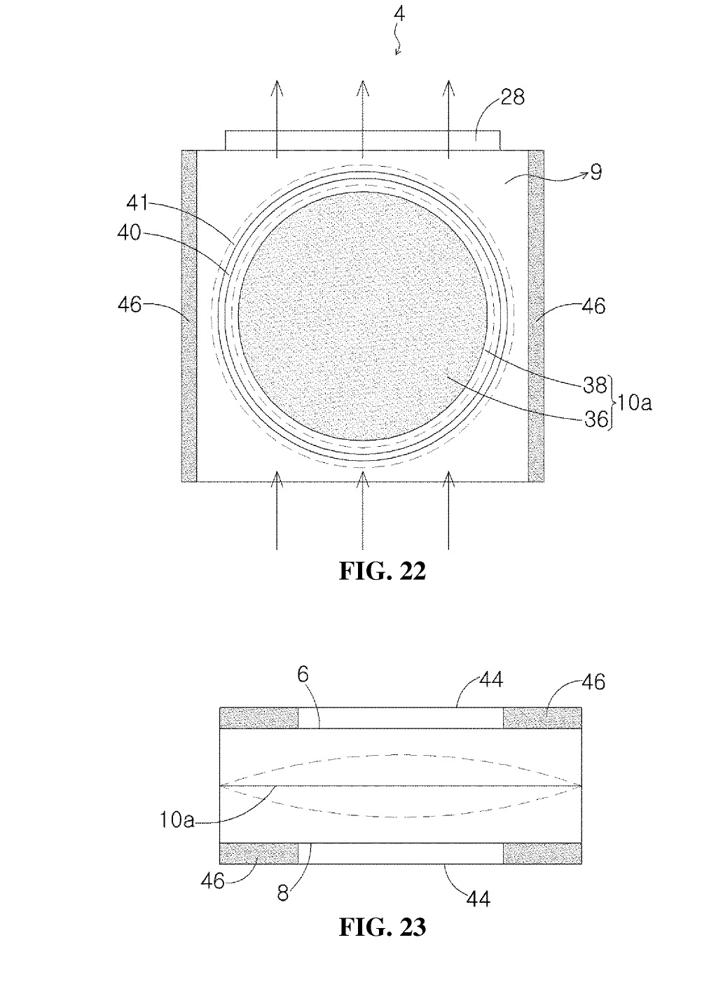

That is, as illustrated in FIG. 22, since the air circulation case 44 is installed such that the back thereof is open to allow the introduction of outside air, while the air inside the air jet device is jetted via the bending displacement of the piezoelectric plate 10a, outside air supplied from the back of the case 44 is jetted along with the air introduced between the case 44 and the air jet device 4, thereby being supplied to the interior of the electronic appliance.

Accordingly, dissipating heat by jetting outside air into the electronic appliance is more effective than dissipating heat by repeatedly suctioning and jetting hot air inside the electronic appliance.

The air jet device 4, provided with the air circulation case 44 according to the present invention, may be installed such that the open back of the case is exposed to the outside of the electronic appliance. In addition, the air jet device 4 provided with the air circulation case 44 may be configured so as to be fitted into the electronic appliance. In addition, a structure that serves as the air circulation case 44 may be provided in the electronic appliance, and the air jet device 4 of the present invention may be fitted into the structure. A plurality of air jet devices 4 each provided with the air circulation case 44 may be stacked one above another.

In addition, in the embodiment of the present invention, although the back side of the air circulation case 44 is open, the air circulation case 44 may be installed to surround the entire air jet device 4, and an air communication hole may be formed in the back of the air circulation case to enable the introduction of outside air. One or more air circulation holes may be formed in the back of the air circulation case 44.

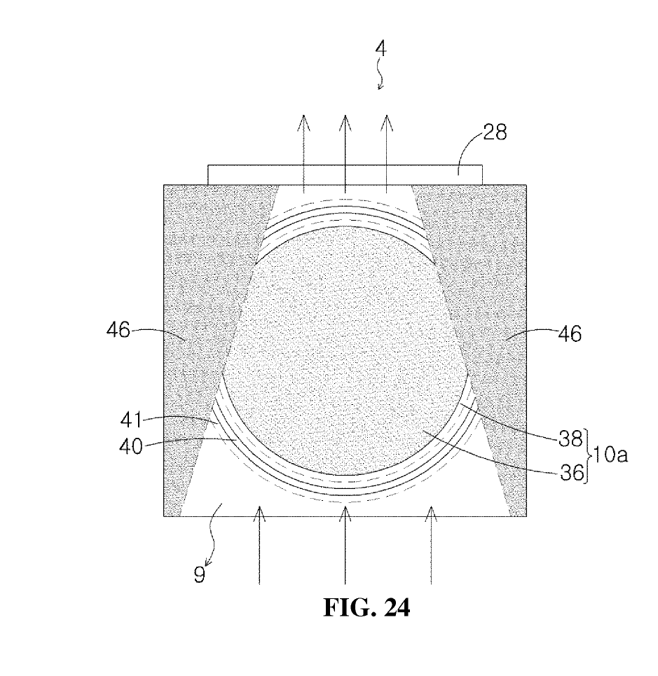

FIGS. 23 and 24 illustrate another shape of the air circulation case 44. In order to allow the air introduced from the back of the air jet device 12 to be circulated forward at a high speed, the air circulation case may be configured to allow the air present at the back thereof to be attracted to the central region of the air passage 12 at which the jet speed of the air is the maximum, which ensures the efficient introduction of air from the back of the air jet device 12.

That is, as the air inside the air jet device 4 is jetted at a high speed, the introduction of air from the back of the air jet device 4 may be effectively accomplished.

As is apparent from the above description, the present invention has the effect of efficiently dissipating heat by continuously discharging air using a single actuator in order to control the generation of heat from heat generating elements by a cooling apparatus using a piezoelectric element.

In addition, the cooling apparatus may be installed within an electronic appliance without a separate bracket, which ensures easy assembly. In particular, in the case where a plurality of cooling apparatuses is installed such that they are stacked one above another, the cooling apparatuses may be attached to one another, which ensures easy installation.

It will be apparent that, although the preferred embodiments have been shown and described above, the disclosure is not limited to the above-described specific embodiments, and various modifications and variations can be made by those skilled in the art without departing from the gist of the appended claims. Accordingly, the scope of the present invention should not be limited to the above description of the embodiment, but defined by the accompanying claims and equivalents thereof.

1. A cooling jet apparatus using a piezoelectric element,
wherein the cooling jet apparatus comprises an air jet device 4 defining a space via sealing coupling of upper and lower walls 6 and 8 formed using a resin material and/or a metal material, a disk type piezoelectric plate 10a being installed across the space to divide the space into first and second chambers 14 and 16,
wherein at least one air passage 12 is formed in one side of the air jet device 4 so as to communicate the space with an outside for introduction or discharge of air into or from the space,
wherein an air division film 28 is formed at one side of the piezoelectric plate 10a so as to protrude from the air passage 12, and serves to separate air to be suctioned from air to be discharged, and
wherein suction and discharge of air occur simultaneously as the first and second chambers 14 and 16 alternately expand and contract by bending displacement of the piezoelectric plate 10a, whereby a heat generating element is cooled via continuous jetting of the air by the air jet device 4.

2. The cooling jet apparatus according to claim 1, wherein the piezoelectric plate 10a includes a ceramic plate member 36 and a conductive metal member 38 configured to provide up-and-down bending displacement, and a film member 41 is attached to an outer circumference of the conductive metal member 38 between the piezoelectric plate 10a and an actuator 9 so as to define an insulation space 40 for insulation of current supplied to the piezoelectric plate 10a and for reduction in vibration noise.

3. The cooling jet apparatus according to claim 1, wherein the piezoelectric plate 10a is provided with a polymer coating layer 35 for insulation at a portion thereof excluding a current supply location.

4. The cooling jet apparatus according to claim 1, wherein the air division film 28 takes the form of 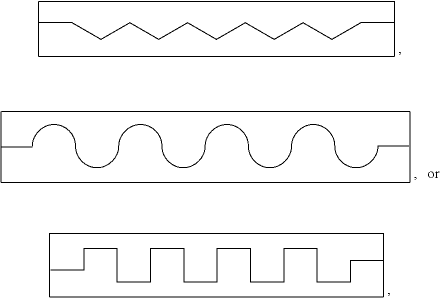
for intensive jetting of the air to be discharged.

5. The cooling jet apparatus according to claim 1, wherein the air passage 12 of the air jet device 4 or 4a is provided with a jet induction surface 22 taking the form of 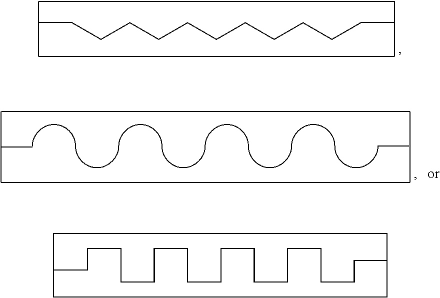
for intensive jetting of the air to be discharged.

6. The cooling jet apparatus according to claim 1, wherein the piezoelectric plate 10a installed in the air jet device 4 has a multilayer structure.

7. The cooling jet apparatus according to claim 1, wherein an air circulation case 44 is provided outside the air jet device 4.

8. A cooling jet apparatus using a piezoelectric element,
wherein the cooling jet apparatus comprises an air jet device 4a defining a space via sealing coupling of upper and lower walls 6 and 8 formed using a resin material and/or a metal material, an elastic layer 30 defining an intermediate layer being formed in the space, and a bender type piezoelectric plate 10b being installed at one side of the elastic layer 30 to divide the space into first and second chambers 14 and 16,
wherein at least one air passage 12 is formed in the lower wall 8 of the air jet device 4a so as to communicate the second chamber 16 with an outside for introduction or discharge of air into or from the second chamber,
wherein at least one auxiliary communication hole 32 is formed in one side of the first chamber 14 of the air jet device 4a so as to communicate the first chamber 14 with the outside for introduction or discharge of air into or from the first chamber, and wherein the first and second chambers 14 and 16 repeatedly expand and contract as the elastic layer 30 having the piezoelectric plate 10b attached thereto moves up and down by up-and-down bending displacement of the piezoelectric plate 10b, whereby a heat generating element is cooled via jetting of air caused by suction and discharge of air through the air passage 12 and the auxiliary communication hole 32.

9. The cooling jet apparatus according to claim 1, wherein the piezoelectric plate 10a or 10b includes any one of unimorph type, bimorph type, and multimorph type piezoelectric elements.

10. The cooling jet apparatus according to claim 1, wherein the piezoelectric plate 10a or 10b is formed of a piezo ceramic.

11. The cooling jet apparatus according to claim 1, wherein the piezoelectric plate 10a or 10b and the elastic layer 30 is formed of any one of a piezo polymer film and an Electro Active Polymer (EAP) film when the air jet device 4 or 4a is very thin and small.

12. The cooling jet apparatus according to claim 1, wherein the air jet device 4 or 4a is installed as any one of the upper wall 6 and the lower wall 8 is attached and fixed.

13. The cooling jet apparatus according to claim 1, wherein the upper wall 6 and the lower wall 8 are provided at the coupling rims thereof with a sealing member 42 configured to prevent the air from moving in a direction excluding the air passage 12 of the air jet device 4 or 4a.

14. The cooling jet apparatus according to claim 8, wherein the elastic layer 30 installed in the air jet device 4a has a multilayer structure.

15. The cooling jet apparatus according to claim 8, wherein the lower wall 8 of the air jet device 4a is provided with an adhesive portion 18 configured to cause the lower wall 8 of the air jet device 4a to be spaced apart from an attachment surface so as to enable movement of the air through the air passage 12.

16. The cooling jet apparatus according to claim 8, wherein the elastic layer 30 included in the air jet device 4a is formed of any one of silicon, urethane, a synthetic resin, and a rubber material.

17. The cooling jet apparatus according to claim 8, wherein the elastic layer 30 is provided at one side thereof with at least one reinforcement rib 20 to increase a bending displacement range of the air jet device 4a caused by the up-and-down bending displacement of the piezoelectric plate 10b.

18. The cooling jet apparatus according to claim 8, wherein the first chamber 14 of the air jet device 4a is provided at any one of a side wall and an upper wall thereof with an auxiliary communication hole 32a, 32b or 32c used to cool the heat generating element via discharge of air inside the first chamber 14.

19. A cooling jet apparatus using a piezoelectric element, wherein the cooling jet apparatus comprises an air jet device 4 defining a space via sealing coupling of upper and lower walls 6 and 8 formed using a resin material and/or a metal material, an elastic layer 30 defining an intermediate layer being formed in the space, and a bender type piezoelectric plate 10b being installed at one side of the elastic layer 30 to divide the space into first and second chambers 14 and 16,
wherein at least one air passage 12 is formed in one side of the air jet device 4 so as to communicate the space with an outside for introduction or discharge of air into or from the space,
wherein an air division film 28 is formed at one side of the piezoelectric plate 10b so as to protrude from the air passage 12, and serves to separate air to be suctioned from air to be discharged, and
wherein suction and discharge of air occur simultaneously as the first and second chambers 14 and 16 alternately expand and contract as the elastic layer 30 moves up and down by bending displacement of the piezoelectric plate 10b, whereby a heat generating element is cooled via continuous jetting of the air by the air jet device 4.

20. A cooling jet apparatus using a piezoelectric element,
wherein the cooling jet apparatus comprises an air jet device 4a defining a space via sealing coupling of upper and lower walls 6 and 8 formed using a resin material and/or a metal material, a disk type piezoelectric plate 10a being installed across the space to divide the space into first and second chambers 14 and 16,
wherein at least one air passage 12 is formed in the lower wall 8 of the air jet device 4a so as to communicate the second chamber 16 with an outside for introduction or discharge of air into or from the second chamber,
wherein at least one auxiliary communication hole 32 is formed in one side of the first chamber 14 of the air jet device 4a so as to communicate the first chamber 14 with the outside for introduction or discharge of air into or from the first chamber, and
wherein the first and second chambers 14 and 16 repeatedly expand and contract by bending displacement of the piezoelectric plate 10a, whereby a heat generating element is cooled via jetting of air caused by suction and discharge of air through the air passage 12 and the auxiliary communication hole 32.
